(19) United States
(12) Patent Application Publication
(10) Pub. No.: US 2024/0170502 A1
(43) Pub. Date: May 23, 2024

(54) DISPLAY PANEL AND DISPLAY APPARATUS

(71) Applicant: WUHAN TIANMA MICRO-ELECTRONICS CO., LTD., Wuhan (CN)

(72) Inventor: Wenshuai ZHANG, Wuhan (CN)

(73) Assignee: WUHAN TIANMA MICRO-ELECTRONICS CO., LTD., Wuhan (CN)

(21) Appl. No.: 18/425,159

(22) Filed: Jan. 29, 2024

(30) Foreign Application Priority Data
Jul. 11, 2023 (CN) 202310847690.3

(51) Int. Cl. H01L 27/12

(52) U.S. Cl. CPC H01L 27/1244

(57) ABSTRACT

A display panel includes a non-display region and a display region. A first non-display sub-region of the non-display region includes multiplexers and first connection lines, and the multiplexer is electrically connected to a first end of the first connection line. A display region includes a first display sub-region and a second display sub-region. The first display sub-region and the first non-display sub-region are arranged along a second direction crossing the first direction. The display region includes first signal lines arranged along the first direction and second connection lines. The first connection lines include a first connection sub-line and a second connection sub-line. The first signal line in the first display sub-region is electrically connected to a second end of the first connection sub-line, and the first signal line in the second display sub-region is electrically connected to a second end of the second connection sub-line through the second connection line.

### CROSS-REFERENCE TO RELATED DISCLOSURE

The present disclosure claims priority to Chinese Patent Application No. 202310847690.3, filed on Jul. 11, 2023, the content of which is incorporated herein by reference in its entirety.

### TECHNICAL FIELD

The present disclosure relates to the display field, and in particular, to a display panel and a display apparatus.

### BACKGROUND

In recent years, display panels with a narrow bezel or bezel-less display panels have become an important development direction of high-end displays. Progress has been made toward narrow bezel display panels. For example, a shift register circuit that was arranged in a frame region is arranged in a display region to narrow the left and right frame regions.

However, reducing the width of the lower frame region, where a driver chip is bonded, in the display panel remains a great challenge. The lower frame region is provided with more complex circuits, signal lines, pins, etc., and it is more difficult to reduce the width of the lower frame region.

### SUMMARY

A first aspect of the present disclosure provides a display panel. In an embodiment, the display panel includes a display region and a non-display region. In an embodiment, the non-display region includes a first non-display sub-region. In an embodiment, multiple multiplexers and multiple first connection lines are arranged in the first non-display sub-region. In an embodiment, each multiplexer includes at least two selection output terminals, the selection output terminal of the multiplexer is electrically connected to a first end of one of multiple first connection lines. In an embodiment, the display region includes a first display sub-region and a second display sub-region located on at least one side of the first display sub-region along a first direction. In an embodiment, the first display sub-region and the first non-display sub-region are arranged along a second direction that crosses the first direction. In an embodiment, each of the first display sub-region and the second display sub-region is provided with multiple first signal lines arranged along the first direction. In an embodiment, the display region further includes multiple second connection lines. In an embodiment, multiple first connection lines include a first connection sub-line and a second connection sub-line, the first signal line in the first display sub-region is electrically connected to a second end of the first connection sub-line, and the first signal line in the second display sub-region is electrically connected to a second end of the second connection sub-line through the second connection line.

A second aspect of the present disclosure provides a display apparatus. In an embodiment, the display apparatus includes the display panel provided in the first aspect.

### DRAWINGS

In order to more clearly illustrate the technical solutions in the embodiments of the present disclosure, the accompanying drawings used in the description of the embodiments will be briefly introduced below. The accompanying drawings in the following description are only some embodiments of the present disclosure, and other drawings can be obtained by those of ordinary skill in the art from the provided drawings.

FIG. 1 is a schematic diagram of a display panel according to one or more embodiments of the present disclosure;

FIG. 2 is a partial schematic diagram of a display panel associated with the present disclosure;

FIG. 3 is a partial schematic diagram of the display panel in FIG. 1 according to one or more embodiments of the present disclosure;

FIG. 4 is a partial schematic diagram of a display panel according to one or more embodiments of the present disclosure;

FIG. 5 is a partial schematic diagram of a display panel according to one or more embodiments of the present disclosure;

FIG. 6 is a schematic diagram showing partial details of FIG. 4 according to one or more embodiments of the present disclosure;

FIG. 7 is a schematic diagram showing partial details of FIG. 5 according to one or more embodiments of the present disclosure;

FIG. 8 is a partial schematic diagram of a display panel according to one or more embodiments of the present disclosure;

FIG. 9 is a partial schematic diagram of a display panel according to one or more embodiments of the present disclosure;

FIG. 10 is a partial schematic diagram of a display panel according to one or more embodiments of the present disclosure;

FIG. 11 is a cross-sectional view taken along line M1-M2 in FIG. 10 according to one or more embodiments of the present disclosure;

FIG. 12 is a partial schematic diagram of a display panel according to one or more embodiments of the present disclosure;

FIG. 13 is a partial schematic diagram of a display panel according to one or more embodiments of the present disclosure;

FIG. 14 is a partial schematic diagram of a display panel according to one or more embodiments of the present disclosure;

FIG. 15 is a partial schematic diagram of a display panel according to one or more embodiments of the present disclosure;

FIG. 16 is a partial schematic diagram of a display panel according to one or more embodiments of the present disclosure;

FIG. 17 is a cross-sectional view taken along line N1-N2 in shown FIG. 16 according to one or more embodiments of the present disclosure; and

FIG. 18 is a schematic diagram of a display apparatus according to one or more embodiments of the present disclosure.

### DESCRIPTION OF EMBODIMENTS

In order to better understand the technical solution of the present disclosure, embodiments of the present disclosure are described in detail below with reference to the accompanying drawings.

It should be noted that, the described embodiments are merely exemplary embodiments of the present disclosure, which shall not be interpreted as providing limitations to the present disclosure. All other embodiments obtained by those skilled in the art according to the embodiments of the present disclosure are within the scope of the present disclosure.

Terms used in the embodiments of the present disclosure are only for the purpose of describing specific embodiments, and are not intended to limit the present disclosure. Unless otherwise specified in the context, words, such as “a”, “the”, and “this”, in a singular form in the embodiments of the present disclosure and the appended claims include plural forms.

It should be understood that the term “and/or” used herein merely indicates a relationship describing associated objects, indicating three possible relationships. For example, the expression “A and/or B” indicates: A exists alone, both A and B exist, or B exists alone. In addition, the character “/” in this description generally means that the associated objects are in an “or” relationship.

For this specification, it should be understood that the terms “basically”, “approximately”, “about”, “generally” and “substantially” described in claims and embodiments of the present disclosure refer to a substantially approved value, rather than an exact value, within a reasonable process operation range or tolerance range.

It should be understood that although the terms “first”, “second”, “third”, and so on may be used to describe multiplexers and lines in embodiments of the present disclosure, these multiplexers and connection lines should not be limited to these terms. These terms are used only to distinguish different multiplexers or different connection lines from each other. For example, without departing from the scope of the embodiments of the present disclosure, a first multiplexer may also be referred to as a second multiplexer, and similarly, a second multiplexer may also be referred to as a first multiplexer.

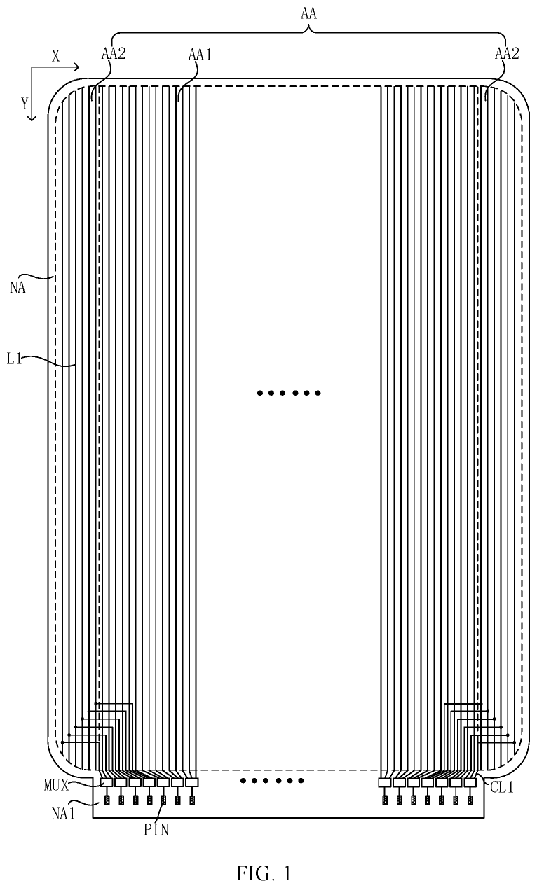

FIG. 1 is a schematic diagram of a display panel according to one or more embodiments of the present disclosure.

Embodiments of the present disclosure provide a display panel. As shown in FIG. 1, the display panel includes a display region AA and a non-display region NA. The non-display region NA at least partially surrounds the display region AA. The display region AA is a main region of the display panel for emitting light and display. The non-display region NA is a main region of the display panel for arranging a periphery circuit and encapsulation.

The display region AA includes multiple first signal lines L1 arranged along a first direction X. The first signal line L1 may extend substantially along a second direction Y. The first direction X crosses the second direction Y. For example, the first direction X is perpendicular to the second direction Y. The first signal line L1 may supply a signal to a pixel circuit in the display region AA or supply a signal to a light-emitting element in the display region AA. For example, the display region may include the pixel circuit, and the first signal line L1 may supply a data voltage to the pixel circuit. In this regard, the first signal line L1 is a data line.

The non-display region NA includes a first non-display sub-region NA1. That is, a part of the non-display region NA is the first non-display sub-region NA1. For example, as shown in FIG. 1, the first non-display sub-region NA1 is a part of the non-display region NA below the display region AA, and the first non-display sub-region NA1 and the display region AA are arranged along the second direction Y.

In embodiments of the present disclosure, as shown in FIG. 1, multiple multiplexers MUX and multiple first connection lines CL1 are arranged in the first non-display sub-region NM. The multiplexer MUX includes at least two selection output terminals, each selection output terminal of the multiplexer MUX is electrically connected to a first end of one first connection line CL1, and a second end of the first connection line CL2 is electrically connected to a data line. That is, the first connection line CL1 is provided between the selection output terminal of the multiplexer MUX and the first signal line L1 and is configured to electrically connect the selection output terminal and the first signal line L1. A number of a selection input terminal of the multiplexer MUX is smaller than the number of the selection output terminals. A signal at the selection input terminal of the multiplexer MUX can be transmitted, in a time division manner, to different selection output terminals, and then is transmitted to different first signal lines L1.

As shown in FIG. 1, the display region AA includes a first display sub-region AA1 and a second display sub-region AA2 located on at least one side of the first display sub-region AA1 along the first direction X. That is, the display region AA is divided, along the first direction X, at least the first display sub-region AA1 and the second display sub-region AA2. For example, as shown in FIG. 1, the display region AA includes one first display sub-region AA1 and two second display sub-regions AA2, and the two second display sub-regions AA2 are respectively located at two sides of the first display sub-region AA1 along the first direction X. Each of the first display sub-region AA1 and the second display sub-region AA2 is provided with multiple first signal lines L1 arranged along the first direction X. That is, some of multiple first signal lines L1 in the display region AA are located in the first display sub-region AA1, and another some of multiple first signal lines L1 in the display region AA are located in the second display sub-region AA2.

The first display sub-region AA1 and the first non-display sub-region NA1 are arranged along the second direction Y. The first non-display sub-region NA1 includes the multiplexer MUX and the first connection line CL1. The first non-display sub-region NA1 may be a region of the non-display region NA that is arranged with the first display region AA1 along the second direction Y. As shown in FIG. 1, a width of the first non-display sub-region NA1 may be smaller than a width of the display region AA along the first direction X. For example, the width of the first non-display sub-region NA1 may substantially equal to the width of the display region AA along the first direction X.

In addition, along the first direction X, the second display sub-region AA2 may at least partially protrude from the first non-display sub-region NM. A shape of the second non-display sub-region NA2 may include a chamfer to achieve a higher screen-to-body ratio.

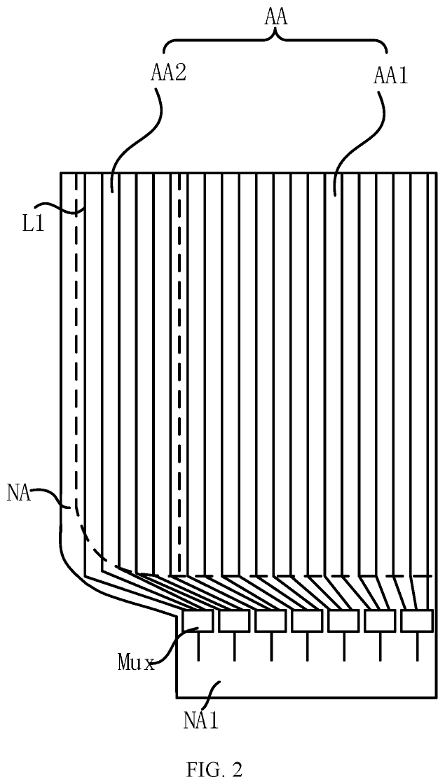

FIG. 2 is a partial schematic diagram of a display panel associated with the present disclosure.

As shown in FIG. 2, along the second direction Y, the second display sub-region AA2 does not overlap with the first non-display sub-region NAll in which the multiplexers MUX are provided. Therefore, when the first signal line L1 in the second display sub-region AA2 is electrically connected to the selection output terminal of the multiplexer MUX in the first non-display sub-region NA1 through the connection line in the non-display region NA, these connection lines in the non-display region NA extend with a large tilt angle, causing a short-circuiting risk. In addition, the width of the position of these connection lines arranged in the non-display region is large, which is not helpful to achieve a small screen-to-body ratio.

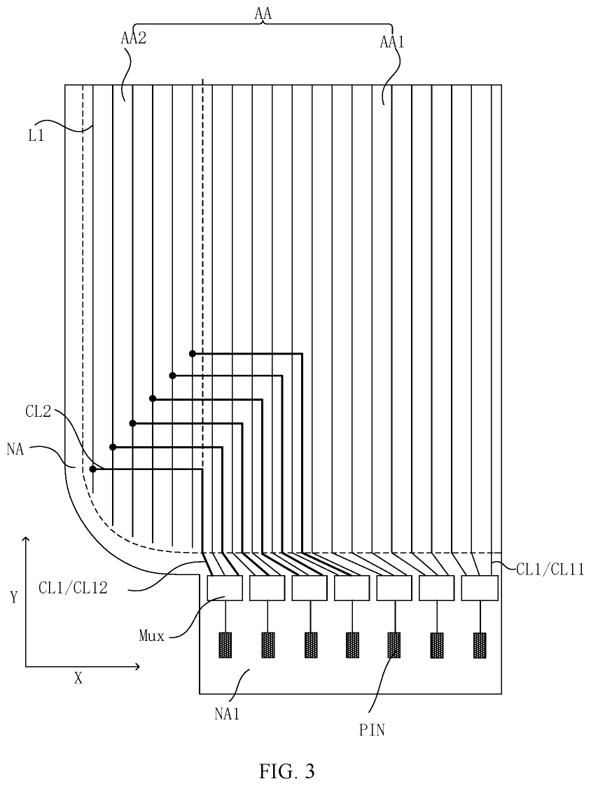

FIG. 3 is a partial schematic diagram of the display panel in FIG. 1.

In some embodiments of the present disclosure, as shown in FIG. 1 and FIG. 3, the display region AA further includes multiple second connection lines CL2. The first signal line L1 in the second display sub-region AA2 is electrically connected to the first connection line CL1 in the first non-display sub-region NA1 through the second connection line CL2 in the display region AA, and then is electrically connected to the selection output terminal of the multiplexer MUX in the first non-display sub-region NA1. That is, the non-display region NA except for the first non-display sub-region NA1 no longer includes the connection line between the first signal line CL1 in the second display sub-region AA2 and the selection output terminal of the multiplexer MUX. In this way, a small screen-to-body ratio is achieved, and the short-circuiting risk of the connection line is reduced.

As shown in FIG. 1 and FIG. 3, multiple first connection lines CL1 include a first connection sub-line CL11 and a second connection sub-line CL12. That is, some of multiple first connection lines CL1 are the first connection sub-lines CL11, and some of multiple first connection lines CL1 are the second connection sub-lines CL12. The selection output terminal of the multiplexer MUX is electrically connected to a first end of the first connection sub-line CL11, and the first signal line L1 in the first display sub-region AA1 is electrically connected to a second end of the first connection sub-line CL11. The selection output terminal of the multiplexer MUX is electrically connected to a first end of the second connection sub-line CL12, and the first signal line L1 in the second display sub-region AA2 is electrically connected to a second end of the second connection sub-line CL12 through the second connection line CL2. In this way, the second end of the first connection sub-line CL11 may be connected to the first signal line L1 in the first display sub-region AA1, the second end of the second connection sub-line CL12 is connected to one end of the second connection line CL2, and the other end of the second connection line CL2 is connected to the first signal line L1 in the second display sub-region AA2.

If the first signal lines L1 in the display region AA are all electrically connected, through the first connection lines CL1 in the first non-display sub-region NA1, to pins PIN rather than the multiplexers MUX, the first connection lines CL1 in the first non-display sub-region NA1 are arranged in a fan-shaped layout. In this case, the short-circuiting risk of the first connection lines CL1 in the first non-display sub-region NA1 along the first direction X is increased, and the layout difficulty of the first connection lines CL1 in the first non-display sub-region NA1 is increased.

In embodiments of the present disclosure, the first signal line L1 in the second display sub-region AA2 is electrically connected to the first connection line CL1 in the first non-display sub-region NA1 through the second connection line CL2, but the first connection lines CL1 in the first non-display sub-region NA1 are all electrically connected to the multiplexers MUX. In this way, the layout difficulty of the connection lines in the first non-display sub-region NA1 is reduced. On the one hand, the multiplexers MUX are located between the first connection lines CL1 and the pins PIN, the first connection lines CL1 are short, the width occupied by the multiplexers MUX arranged along the first direction X is larger than the width, along the first direction X, occupied by the pins PIN corresponding to the multiplexers MUX. Therefore, the short-circuiting risk between adjacent first connection lines CL1 is reduced, and the layout difficulty is reduced. On the other hand, the number of the connection lines between the multiplexers MUX and the pins PIN electrically connected to the multiplexers MUX is reduced, the short-circuiting risk and the layout difficulty of these connection lines are reduced significantly.

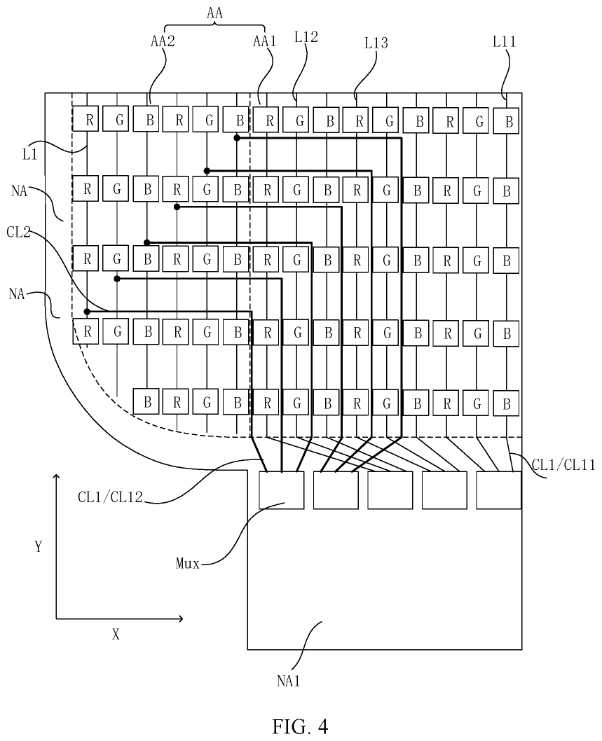

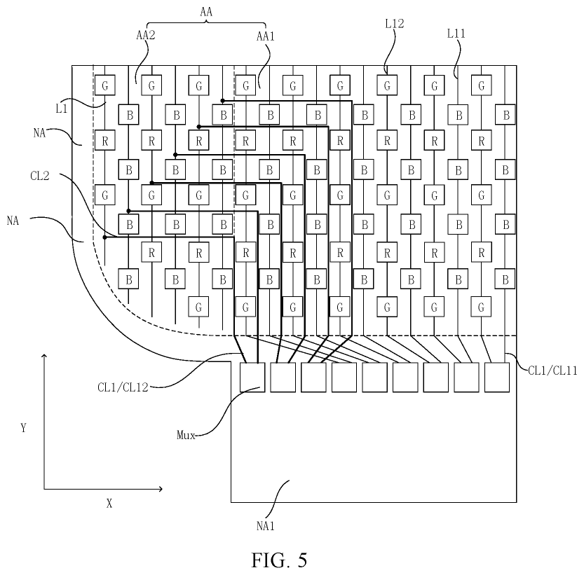

FIG. 4 is a partial schematic diagram of a display panel according to one or more embodiments of the present disclosure. FIG. 5 is a partial schematic diagram of a display panel according to one or more embodiments of the present disclosure.

As shown in FIG. 4 and FIG. 5, multiple first signal lines L1 include Type-1 signal lines to Type-M signal lines, where M is a positive integer greater than 2. Among the Type-1 signal lines to the Type-M signal lines, colors of sub-pixels that are electrically connected to the first signal lines L1 of the same type are consistent, and at least part of sub-pixels electrically connected to the first signal lines L1 of different types are of different colors.

As shown in FIG. 4, M=3, that is, multiple first signal lines L1 in the display region AA include Type-1 signal lines L11, second type signal lines L12, and third type signal lines L13. The colors of the sub-pixels electrically connected to the Type-1 signal lines L11 are consistent. For example, the sub-pixels electrically connected to the Type-1 signal lines L11 are blue sub-pixels B. The colors of the sub-pixels electrically connected to the second type signal lines L12 are consistent. For example, the sub-pixels electrically connected to the second type signal lines L12 are green sub-pixels G. The colors of the sub-pixels electrically connected to the third type signal lines L13 are consistent. For example, the sub-pixels electrically connected to the third type signal lines L13 are red sub-pixels R. The color of the sub-pixel electrically connected to the Type-1 signal line L11, the color of the sub-pixel electrically connected to the second type signal line L12, and the color of the sub-pixel electrically connected to the third type signal line L13 are different from each other.

As shown in FIG. 5, M=2. That is, multiple first signal lines L1 in the display region AA include Type-1 signal lines L11 and second type signal lines L12. The colors of the sub-pixels electrically connected to the Type-1 signal lines L11 are consistent. For example, the sub-pixels electrically connected to the Type-1 signal lines L11 are blue sub-pixels B. The colors of the sub-pixels electrically connected to the second type signal lines L12 are consistent. For example, the sub-pixels electrically connected to each second type signal line L12 are green sub-pixels G and red sub-pixels R. The color of the sub-pixel electrically connected to the Type-1 signal line L11 and the color of the sub-pixel electrically connected to the second type signal line L12 are different from each other.

It should be noted that the colors of the sub-pixels electrically connected to first signal lines L1 of the same type are consistent, but it does not limit the present disclosure to that each first signal line L1 of the first signal lines L1 of the same type can only be electrically connected to sub-pixels of the same color. Each first signal line L1 of the first signal lines L1 of the same type may electrically connected to sub-pixels of the same color. For example, as shown in FIG. 4, all Type-1 signal lines L11 are electrically connected to blue sub-pixels B, all second type signal lines L12 are electrically connected to green sub-pixels G, and all third type signal lines L13 are electrically connected to red sub-pixels R. For another example, as shown in FIG. 5, all Type-1 signal lines L11 are electrically connected to blue sub-pixels B. Each Type-1 signal line L11 of at least part of the first signal lines L1 of the same type are electrically connected to sub-pixels of different colors. For example, as shown in FIG. 5, the second type signal line L12 is electrically connected to red sub-pixels R and green sub-pixels G.

It should be noted that at least part of sub-pixels electrically connected to the first signal lines L1 of different types have different colors, but it does not mean that the colors of the sub-pixels electrically connected to the first signal lines L1 of different types are completely different. For example, some sub-pixels of the sub-pixels electrically connected to the first signal lines L1 of different types have the same color, and some sub-pixels have different colors.

In some embodiments of the present disclosure, as shown in FIG. 4 and FIG. 5, each multiplexer MIX is electrically connected to the Type-1 signal line L11 to the Type-M signal line. That is, the same multiplexer MIX is electrically connected to signal lines of different types, and the types of the signal lines electrically connected to different multiplexers MIX have no difference. In embodiments of the present disclosure, the multiplexer MIX includes M selection output terminals, and the M selection output terminals are electrically connected to the Type-1 signal line L11 to the Type-M signal line respectively.

Multiple first signal lines L1 in the display region AA include the Type-1 signal lines L11 to the Type-M signal lines, and multiple selection output terminals of the multiplexer MIX are electrically connected to the Type-1 signal line L11 to the Type-M signal line respectively. In this way, the multiplexer MIX can supply different signals received at the selection input terminal to the Type-1 signal line L11 to the Type-M signal line in the time division manner. The selection output of each multiplexer MIX can be easily controlled, and the coordinated control of different multiplexers MIX is easy to achieve.

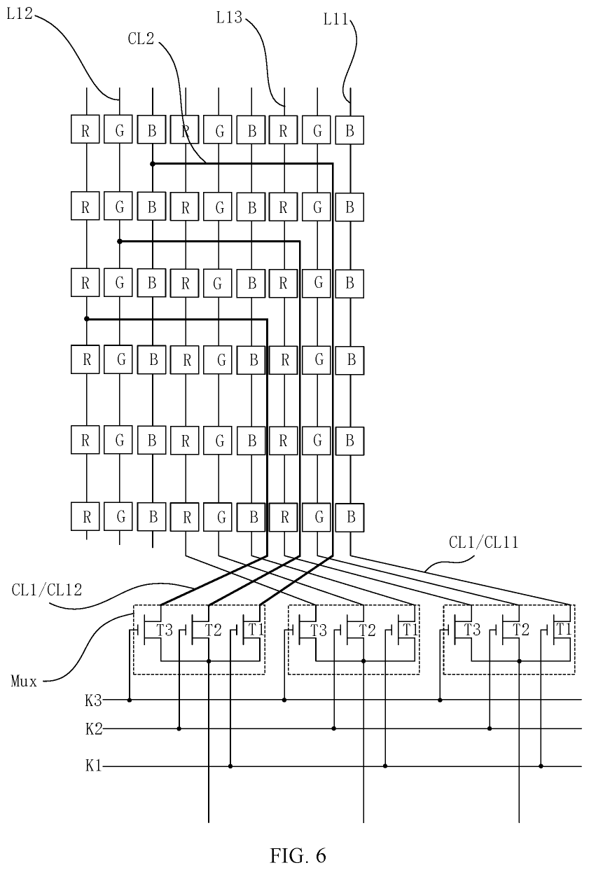

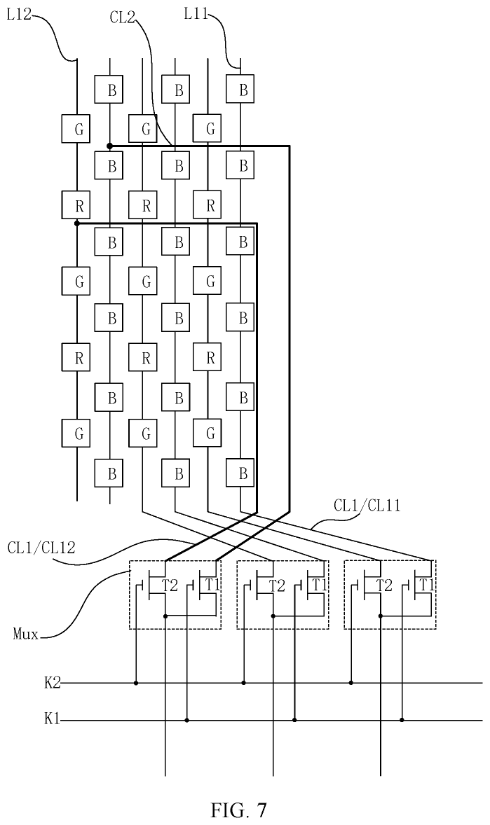

FIG. 6 is a schematic diagram showing partial details of FIG. 4. FIG. 7 is a schematic diagram showing partial details of FIG. 5.

As shown in FIG. 6 and FIG. 7, when multiple selection output terminals of the multiplexer MUX are electrically connected to the Type-1 signal line L11 to the Type-M signal line respectively, the multiplexer MUX includes a Type-1 switch T1 to the Type-M switch. Output terminals of the Type-1 switch T1 to the Type-M switch of the same multiplexer MUX are respectively electrically connected to the Type-1 signal line L11 to the Type-M signal line respectively, and control terminals of the Type-1 switch T1 to the Type-M switch of the same multiplexer MUX are respectively electrically to a first control line K1 to a Mth control line. For example, as shown in FIG. 6, M=3, multiple selection output terminals of the multiplexer MUX are respectively connected to the Type-1 signal line L11, the second type signal line L12, and the third type signal line L13, the multiplexer MUX includes the Type-1 switch T1, the second type switch T2, and the third type switch T3. The output terminals of the Type-1 switch T1, the second type switch T2, and the third type switch T3 of the same multiplexer MUX are respectively connected to the Type-1 signal line L11, the second type signal line L12, and the third type signal line L13, and the control terminals of the Type-1 switch T1, the second type switch T2, and the third type switch T3 of the same multiplexer MUX are respectively connected to the first control line K1, the second control line K2, and the third control line K3. For example, as shown in FIG. 7, M=2, multiple selection output terminals of the multiplexer MUX are respectively connected to the Type-1 signal line L11 and the second type signal line L12, the multiplexer MUX includes the Type-1 switch T1 and the second type switch T2. The output terminals of the Type-1 switch T1 and the second type switch T2 of the same multiplexer MUX are respectively connected to the Type-1 signal line L11 and the second type signal line L12, and the control terminals of the Type-1 switch T1 and the second type switch T2 of the same multiplexer MUX are respectively connected to the first control line K1 and the second control line K2.

In some embodiments, input terminals of the Type-1 switch T1 to the Type-M switch of the same multiplexer MUX may be electrically connected together, and the Type-1 switch T1 to the Type-M switch are turned on in a time division manner such that the signal received by the input terminal is transmitted to the Type-1 signal line L11 to the Type-M signal line in the time division manner. For example, as shown in FIG. 6, M=3, the Type-1 switch T1, the second type switch T2, and the third type switch T3 are turned on in the time division manner, and the signal received by the input terminal is transmitted to the Type-1 signal line L11, the second type signal line L12, and the third type signal line L13 in the time division manner. For another example, as shown in FIG. 7, M=2, the Type-1 switch T1 and the second type switch T2 are turned on in the time division manner, and the signal received by the input terminal is transmitted to the Type-1 signal line L11 and the second type signal line L12 in the time division manner.

In some embodiments, the control terminals of the j^{th} type switches of different multiplexers MUX may be connected to the j^{th} control line, 1≤j≤M. Therefore, the first signal lines L1 of the same type can be controlled to perform data inputting at the same time. For example, as shown in FIG. 6, M=3, and the control terminals of the Type-1 switch T1, the second type switch T2, and the third type switch T3 are respectively electrically connected to the first control line K1, the second control line K2, and the third control line K3. For another example, as shown in FIG. 7, M=2, and the control terminals of the Type-1 switch T1 and the second type switch T2 are respectively electrically connected to the first control line K1 and the second control line K2.

It should be noted that the switch is represented by a transistor in the drawings, and the control terminal of the switch is the gate electrode of the transistor. However, the switch may be implemented by manners other than the transistor.

In some embodiments of the present disclosure, the first signal line L1 in the second display sub-region AA2 is electrically connected to the multiplexer MUX via the second connection line CL2 in the display region AA and the first connection line CL1 in the first non-display sub-region NA1, and the arrangement sequence of multiple first signal lines L1 in the display region AA that are arranged along the first direction X is different from the arrangement sequence of the first connection line CL1 that are arranged along the first direction X and electrically connected to multiple first signal lines L1. However, each of different multiplexer MUX is electrically connected to the Type-1 signal line L11 to the Type-M signal line, the selection output of each multiplexer MUX is easy to control, and the coordinated control of different multiplexers MIX is easy to achieve.

The concept of the present disclosure is described below with an example in which M=3. It should be noted that M may be 2 or a positive integer greater than 3.

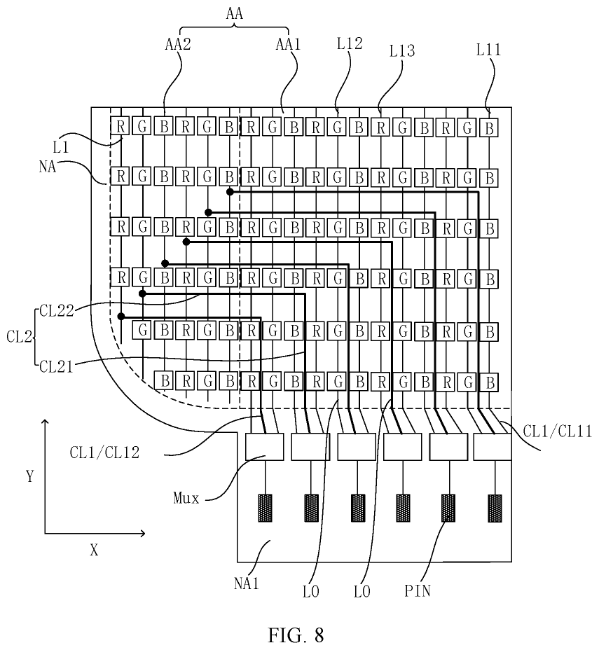

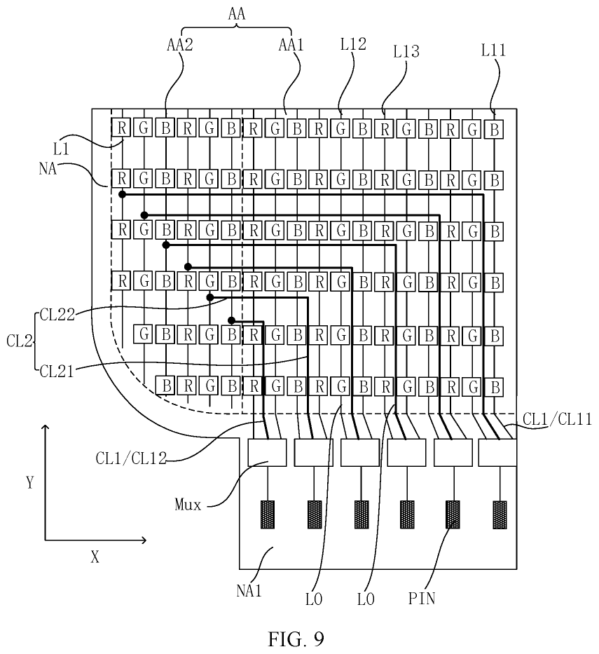

FIG. 8 is a partial schematic diagram of a display panel according to one or more embodiments of the present disclosure. FIG. 9 is a partial schematic diagram of a display panel according to one or more embodiments of the present disclosure.

In an embodiment of the present disclosure, as shown in FIG. 8 and FIG. 9, the second connection line CL2 includes a first portion CL21 and a second portion CL22. The second portion CL22 is connected between the first portion CL21 and the first signal line L1 in the second display sub-region AA2. The first portion CL21 may extend along the second direction Y, and the second portion CL22 may extend along the first direction X. An included angel between the first portion CL21 and the second portion CL22 is a right angle. In another embodiment, the included angel between the first portion CL21 and the second portion CL22 may be greater than 90°. In some other embodiments, the first portion CL 21 and the second portion CL 22 are not straight lines.

The first portions CL21 of multiple second connection lines CL2 are arranged along the first direction X. The first portion CL21 may be a segment of the second connection line CL2 that is connected to the first connection line CL1, and the second portion CL22 may be a segment of the second connection line CL2 that is connected to the first signal line L1 in the second display sub-region AA2. The first portion CL21 and the first signal line L1 in the first display sub-region AA1 are all proximity signal lines L0. That is, the first signal line L1 and the first portion CL21 connected to the first connection line CL1 are referred to as the proximity signal lines L0.

Multiple multiplexers MUX in the first non-display sub-region NA1 each include multiple selection output terminals. For example, the first non-display sub-region NA1 includes N multiplexers MUX, and each of the N multiplexers MUX includes M selection output terminals. Accordingly, the multiplexers MUX in the first non-display sub-region NA1 include M*N selection output terminals. In embodiments of the present disclosure, the arrangement sequence along the first direction X of the selection output terminals of the multiplexers MUX in the first non-display sub-region NA1 is the same as the arrangement sequence along the first direction X of the proximity signal lines L0 that are electrically connected to the selection output terminals. The proximity signal line L0 is electrically connected to its proximity selection output terminal, thereby reducing the layout difficulty of the first connection lines CL1.

In some embodiments, by setting the positions of the first portions CL21 in the first direction X, each multiplexer MUX is electrically connected to the Type-1 signal line L11 to the Type-M signal line.

In some embodiments, as shown in FIG. 8, the arrangement sequence along the first direction X of the first signal lines L1 in the second display sub-region AA2 is reverse to the arrangement sequence along the first direction X of the first portions CL21 that are electrically connected to the first signal lines L1. For example, as shown in FIG. 8, the first signal lines L1 in the second display sub-region AA2 are arranged from left to right, and the first portions CL21 respectively electrically connected to the first signal lines L1 are arranged from right to left.

In some embodiments, as shown in FIG. 9, the arrangement sequence along the first direction X of the first signal lines L1 in the second display sub-region AA2 is the same as the arrangement sequence along the first direction X of the first portions CL21 that are electrically connected to the first signal lines L1. For example, as shown in FIG. 9, the first signal lines L1 in the second display sub-region AA2 are arranged from left to right, and the first portions CL21 respectively electrically connected to the first signal lines L1 are also arranged from left to right.

In some embodiments of the present disclosure, as shown in FIG. 8 and FIG. 9, the first non-display sub-region NA1 further includes multiple pins PIN arranged along the first direction X. The pins PIN are electrically connected to the input terminals of the multiplexers MUX. The pin PIN may be electrically connected to the input terminal of the multiplexer MUX through a third connection line. In the present embodiment, the arrangement sequence along the first direction X of multiple pins PIN is the same as the arrangement sequence along the first direction X of the multiplexers MUX electrically connected to the pins PIN, thereby reducing the layout difficulty of the first connection lines CL1.

In some embodiments of the present disclosure, as shown in FIG. 8 and FIG. 9, the multiplexer MUX is electrically connected to at least three first signal lines L1. Among the at least three first signal lines L1 electrically connected to the multiplexer MUX, at least one first signal line L1 is located in the first display sub-region AA1. That is, the multiplexer MUX is electrically connected to at least one first signal line L1 in the first display sub-region AA1.

In some embodiments of the present disclosure, as shown in FIG. 9, the multiplexer MUX is electrically connected to at least three first signal lines L1. Among the at least three first signal lines L1 electrically connected to the multiplexer MUX, at least one first signal line L1 is located in the second display sub-region AA2. That is, the multiplexer MUX is electrically connected to at least one first signal line L1 in the second display sub-region AA2.

In some embodiments of the present disclosure, as shown in FIG. 9, among the at least three first signal lines L1 electrically connected to any multiplexer MUX, at least one first signal line L1 is located in the first display sub-region AA1, and at least one first signal line L1 is located in the second display sub-region AA2. That is, the multiplexer MUX is electrically connected to at least one first signal line L1 in the first display sub-region AA1 and at least one first signal line L1 in the second display sub-region AA2.

In some embodiments of the present disclosure, as shown in FIG. 4 and FIG. 7, each multiplexer MUX is electrically connected to the Type-1 signal line L11 to the Type-M signal line. The Type-1 signal line L11 to the Type-M signal line electrically connected to any multiplexer MUX are sequentially arranged along the first direction X and adjacent to one another. Among the Type-1 signal line L11 to the Type-M signal line electrically connected to the same multiplexer MUX, no other first signal line L1 is provided between any two signal lines that are adjacent along the first direction X. In other words, multiple first signal lines L1 in the display region AA are divided into multiple first signal line groups that are arranged along the first direction X, and each first signal line group includes the Type-1 signal line L11 to the Type-M signal line that are arranged along the first direction X and adjacent to one another. The first signal line groups may be in one-to-one correspondence with the multiplexers MUX, and the Type-1 signal line L11 to the Type-M signal line in one first signal line group are in one-to-one correspondence with and electrically connected to multiple selection output terminals of the corresponding multiplexer MUX.

For example, as shown in FIG. 4 and FIG. 6, M=3, the Type-1 signal line L11, the second type signal line L12, and the third type signal line L13 are sequentially arranged from left to right. The Type-1 signal line L11, the second type signal line L12, and the third type signal line L13 that are sequentially arranged and adjacent to one another define an arrangement unit. The first signal lines L1 in different arrangement units are respectively electrically connected to different multiplexers MUX. The Type-1 signal line L11, the second type signal line L12, and the third type signal line L13 in the same arrangement unit are respectively electrically connected to different selection output terminals of the same multiplexer MUX.

In some embodiments, the first signal lines L1 are divided into groups according to the arrangement sequence of the first signal lines L1, and then the multiplexer MUX is determined for each group of first signal lines L1 for electrical connection. This can reduce the difficulty of supplying signals by a drive chip to the control terminals and input terminals of the multiplexers MUX.

In some embodiments of the present disclosure, as shown in FIG. 4 to FIG. 7, each of multiple multiplexers MUX in the first non-display sub-region NA1 includes multiple selection output terminals. For example, the first non-display sub-region NA1 includes N multiplexers MUX, and each multiplexer MUX includes M selection output terminals. Accordingly, multiple multiplexers MUX in the first non-display sub-region NA1 include M*N selection output terminals.

The selection output terminals of multiple multiplexers MUX in the first non-display sub-region NA1 include Type-1 selection output terminals to Type-M selection output terminals. The Type-1 signal lines L11 to the Type-M signal lines are in one-to-one correspondence with and electrically connected to the Type-1 selection output terminals to the Type-M selection output terminals. That is, the selection output terminal electrically connected to the Type-1 signal line L11 is the Type-1 selection output terminal, the selection output terminal electrically connected to the second type signal line L12 is the second type selection output terminal, . . . , and the selection output terminal electrically connected to the Type-M signal line is the Type-M selection output terminal.

Among the Type-1 signal line L11 to the Type-M signal line corresponding to the same multiplexer MUX and the Type-1 selection output terminal to the Type-M selection output terminal, the arrangement sequence of the Type-1 signal line L11 to the Type-M signal line that are sequentially arranged along the first direction X and adjacent to one another is the same as the arrangement sequence of the Type-1 selection output terminal to the Type-M selection output terminal that are sequentially arranged along the first direction X and adjacent to one another. For example, as shown in FIG. 4 to FIG. 7, the Type-1 selection output terminal to the Type-M selection output terminal of the same multiplexer MUX are sequentially arranged from left to right and adjacent to one another, and the Type-1 signal line L11 to the Type-M signal line electrically connected to the same multiplexer MUX are sequentially arranged from left to right and adjacent to one another.

In the present embodiment, among multiple first signal lines L1 that are arranged along the first direction X and electrically connected to the same multiplexer MUX and multiple selection output terminals that are arranged along the first direction X and included in the same multiplexer MUX, the first signal line L1 closer to an edge at one side is electrically connected to the selection output terminal closer to the edge at the one side, and the first signal line L1 closer to the middle is electrically connected to the selection output terminal closer to the middle, which reduces the layout difficulty of the first connection lines CL1 and the second connection lines CL2.

In some embodiments of the present disclosure, as shown in FIG. 4 to FIG. 7, the arrangement sequence along the first direction X of multiple multiplexers MUX in the first non-display sub-region NA1 is the same as the arrangement sequence along the first direction X of the Type-k signal lines that are electrically connected to multiple multiplexers MUX respectively, where 1≤k≤M.

For example, k=1, as shown in FIG. 4 to FIG. 7, multiple multiplexers MUX in the first non-display sub-region NA1 are arranged along the first direction X from left to right, and multiple Type-1 signal lines L11 respectively electrically connected to multiple multiplexers MUX are arranged along the first direction X from left to right in the display region AA. For another example, k=2, as shown in FIG. 4 to FIG. 7, multiple multiplexers MUX in the first non-display sub-region NA1 are arranged along the first direction X from left to right, and multiple second type signal lines L12 respectively electrically connected to multiple multiplexers MUX are arranged along the first direction X from left to right in the display region AA.

Among the first signal line groups that are located in the display region AA and arranged along the first direction X, the first signal lines L1 in the first signal line group that is closer to the edge along the first direction X are electrically connected to the multiplexer MUX that is closer to the edge along the first direction X, and the first signal lines L1 in the first signal line group that is closer to the middle along the first direction X are electrically connected to the multiplexer MUX that is closer to the middle along the first direction X.

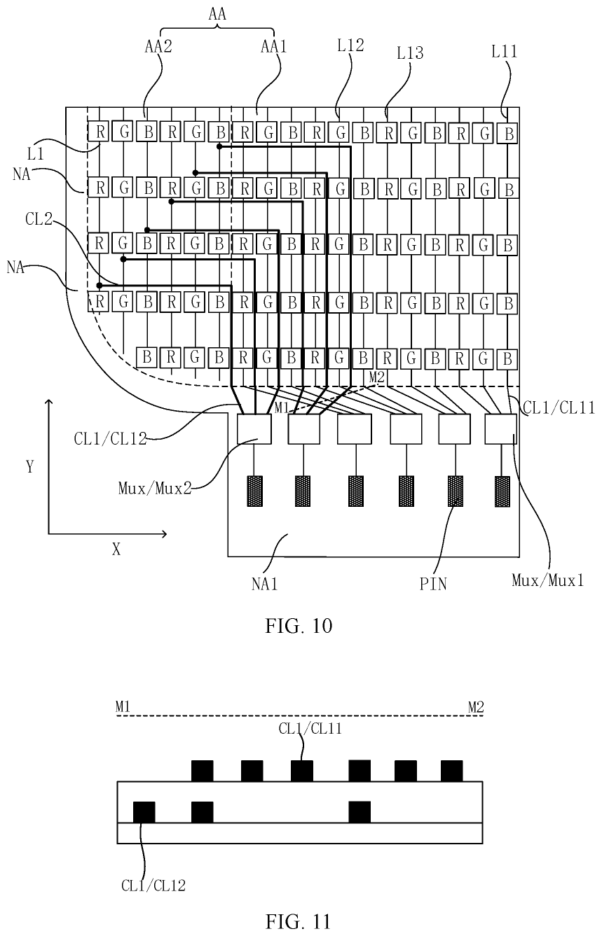

FIG. 10 is a partial schematic diagram of a display panel according to one or more embodiments of the present disclosure.

As shown in FIG. 10, the arrangement sequence along the first direction X of multiple multiplexers MUX in the first non-display sub-region NA1 is the same as the arrangement sequence along the first direction X of the pins PIN that are electrically connected to the input terminals of multiple multiplexers MUX. When the arrangement sequence along the first direction X of the first signal lines L1 of the same type is the same as the arrangement sequence along the first direction X of the multiplexers MUX electrically connected to the first signal lines L1, the arrangement sequence along the first direction X of the pins PIN that are electrically connected to the input terminals of the multiplexers MUX is the same as the arrangement sequence along the first direction X of the corresponding first signal lines L1, and the drive chip bonded with these pins PIN may be a drive chip in the existing art, which can reduce the research cost of the drive chip.

FIG. 11 is a cross-sectional view taken along line M1-M2 in FIG. 10.

The second connection line CL2 includes a first end electrically connected to the first signal line L1, and the first end is located in the second display sub-region AA2. The second connection line CL2 further includes a second end electrically connected to the first connection line CL1, and the second end is located in the first display sub-region AA1 or the first non-display sub-region NM. The second ends, electrically connected to the first connection lines CL1, of some second connection lines CL2 are located at a side of some first signal lines L1 in the first display sub-region AA1 away from the second display sub-region AA2. Therefore, the first connection lines CL1 for connecting these second connection lines CL2 with their corresponding multiplexers MUX cross the first connection lines CL1 for connecting these first signal lines L1 with their corresponding multiplexers MUX. In some embodiments, as shown in FIG. 10 and FIG. 11, the first connection sub-lines CL11 and the second connection sub-lines CL12 may be arranged in different conductive layers, such that the arrangement sequence along the first direction X of multiple multiplexers MUX in the first non-display sub-region NA1 is the same as the arrangement sequence along the first direction X of the Type-k signal lines that are electrically connected to multiple multiplexers MUX respectively, avoiding the short-circuiting risk between the first connection sub-line CL11 and the second connection sub-line CL12.

For the Type-1 signal line L11 to the Type-M signal line and the Type-1 selection output terminal to the Type-M selection output terminal corresponding to the same multiplexer MUX, when the arrangement sequence along the first direction X of the Type-1 signal line L11 to the Type-M signal line is the same as the arrangement sequence along the first direction X of the Type-1 selection output terminal to the Type-M selection output terminal, as shown in FIG. 4, FIG. 7, and FIG. 10, the arrangement sequence along the first direction X of multiple multiplexers MUX in the first non-display sub-region NA1 is the same as the arrangement sequence along the first direction X of the Type-k signal lines that are electrically connected to multiple multiplexers MUX respectively.

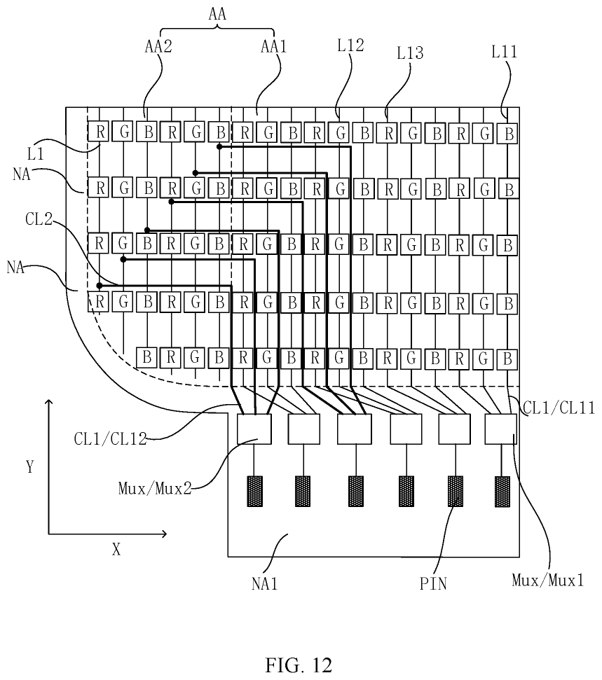

FIG. 12 is a partial schematic diagram of a display panel according to one or more embodiments of the present disclosure.

For the Type-1 signal line L11 to the Type-M signal line and the Type-1 selection output terminal to the Type-M selection output terminal corresponding to the same multiplexer MUX, the arrangement sequence along the first direction X of the Type-1 signal line L11 to the Type-M signal line is the same as the arrangement sequence along the first direction X of the Type-1 selection output terminal to the Type-M selection output terminal. Considering the layout difficulty of the first connection lines CL1, as shown in FIG. 12, the arrangement sequence of the multiplexers MUX electrically connected to the first signal lines L1 in the second display sub-region AA2 is the same as the arrangement sequence of the first signal lines L1 electrically connected to the multiplexers MUX, and the arrangement sequence of the multiplexers MUX electrically connected to the first signal lines L1 in the first display sub-region AA1 is the same as the arrangement sequence of the first signal lines L1 electrically connected to the multiplexers MUX.

In some embodiments of the present disclosure, as shown in FIG. 10 and FIG. 12, multiple multiplexers MUX include a first multiplexer MUX1 and a second multiplexer MUX2. The first multiplexer MUX1 is electrically connected to the first signal lines L1 in the first display sub-region AA1, and the second multiplexer MUX2 is electrically connected to the first signal lines L1 in the second display sub-region AA2. That is, the selection output terminals of the first multiplexer MUX1 are electrically connected to the first signal lines L1 in the first display sub-region AA1 via first connection sub-lines CL11, and the selection output terminals of the second multiplexer MUX2 are electrically connected to the first signal lines L1 in the second display sub-regions AA2 via the second connection sub-lines CL12 and the second connection lines CL2.

In some embodiments of the present disclosure, among the Type-1 signal line L11 to the Type-M signal line electrically connected to the same multiplexer MUX, no other Type-1 first signal line L1 is arranged between any two signal lines that are adjacent and arranged along the first direction X. With the above arrangement, it is easy to achieve that the first multiplexer MUX1 is electrically connected to the first signal lines L1 in the first display sub-region AA1 and the second multiplexer MUX2 is electrically connected to the first signal lines L1 in the second display sub-region AA2.

In some embodiments of the present disclosure, as shown in FIG. 4 to FIG. 7, among multiple first signal lines L1 in the display region AA, some first signal lines L1 are electrically connected to the first multiplexer MUX1, and some first signal lines L1 are electrically connected to the second multiplexer MUX2.

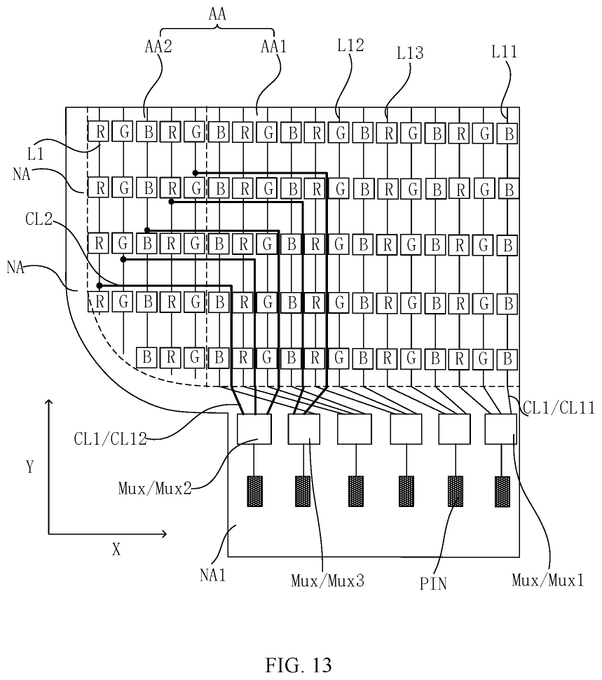

FIG. 13 is a partial schematic diagram of a display panel according to one or more embodiments of the present disclosure.

In some embodiments of the present disclosure, as shown in FIG. 13, multiple multiplexers MUX further include a third multiplexer MUX3. Among the selection output terminals of the third multiplexer MUX3, some selection output terminals are electrically connected to the first signal lines L1 in the first display sub-region AA1 through the first connection sub-lines CL11, and some selection output terminals are electrically connected to the first signal lines L1 in the second display sub-region AA2 through the second connection sub-lines CL12 and the second connection lines CL2. That is, the first non-display sub-region NA1 includes one or more multiplexers MUX, each of which is electrically connected to both the first signal line L1 in the first display sub-region AA1 and the first signal line L1 in the second display sub-region AA2.

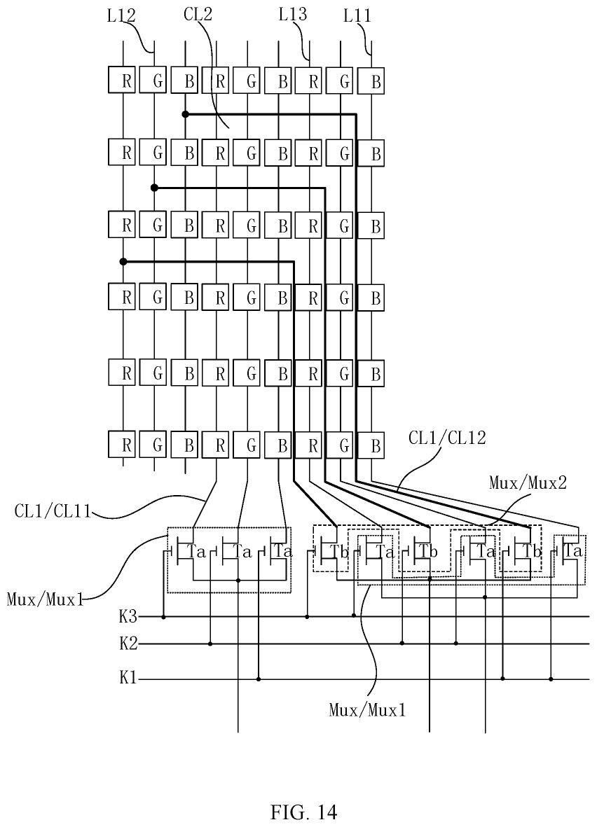

FIG. 14 is a partial schematic diagram of a display panel according to one or more embodiments of the present disclosure.

In some embodiments of the present disclosure, as shown in FIG. 14, multiple multiplexers MUX include a first multiplexer MUX1 and a second multiplexer MUX2. The first multiplexer MUX1 includes multiple first switches Ta, and the second multiplexer MUX2 includes multiple second switches Tb. An output terminal of the first switch Ta is electrically connected to the first signal line L1 in the first display sub-region AA1 through the first connection sub-line CL11. An output terminal of the second switch Tb is electrically connected to the first signal line L1 in the second display sub-region AA2 through the second connection sub-line CL12 and the second connection line CL2. In the present embodiment, the first multiplexer MUX1 may only include the first switches Ta each of which is electrically connected to the first signal line L1 in the first display sub-region AA1, and the second multiplexer MUX2 may only include the second switches Tb each of which is electrically connected to the first signal line L1 in the second display sub-region AA2.

In one or more second multiplexers MUX2, along the first direction X, at least two adjacent second switches Tb in the same second multiplexer MUX2 are spaced apart by the first switch Ta therebetween. That is, in at least one or more second multiplexers MUX2, along the first direction X, at least two second switches Tb in the same second multiplexer MUX2 are respectively located between different first switches Ta that are arranged adjacent. For example, as shown in FIG. 14, the second multiplexer MUX2 includes three second switches Tb. Along the first direction X, the three second switches Tb are respectively located between different first switches Ta that are arranged adjacent. That is, along the first direction X, any adjacent two ones of the three second switches Tb is spaced apart by a different first switch Ta therebetween.

It should be noted that FIG. 14 shows an example embodiment. In the example embodiment, along the first direction X, at least two second switches Tb in any two second multiplexers MUX2 are respectively located between different first switches Ta that are adjacently arranged. But the present disclosure is not limited to this. In an example, along the first direction X, for all second switches Tb in one or more second multiplexers MUX2, there is no first switch Ta between any two second switches Tb.

The output terminal of the second switch Tb is electrically connected to the first portion CL21 in the second connection line CL2 through the second connection sub-line CL12. When one or more second switches Tb are located between two adjacently arranged first switches Ta, one of the one or more second switches Tb closer to the first portion CL21 is the second switch Tb electrically connected to the first portion CL21. Therefore, the layout difficulty of the second connection sub-line CL12 is reduced.

In embodiments of the present disclosure, as shown in FIG. 14, although at least one or more second switches Tb in the second multiplexers MUX2 are distributed between different pairs of first switches Ta arranged adjacently, the output terminals of multiple second switches Tb in the same second multiplexer MUX2 can be electrically connected to the Type-1 signal line L11 to the Type-M signal line respectively. In this way, each multiplexer MUX is electrically connected to the Type-1 signal line L11 to the Type-M signal line.

In some embodiments of the present disclosure, as shown in FIG. 14, in at least one or more first multiplexers MUX1, along the first direction X, at least two adjacent first switches Ta in the same first multiplexer MUX1 are spaced apart by the second switch Tb. The switch closer to the first signal line L1 in the first display sub-region AA1 is selected as the first switch Ta electrically connected to the first signal line L1, thereby reducing the layout difficulty of the first connection sub-line CL11.

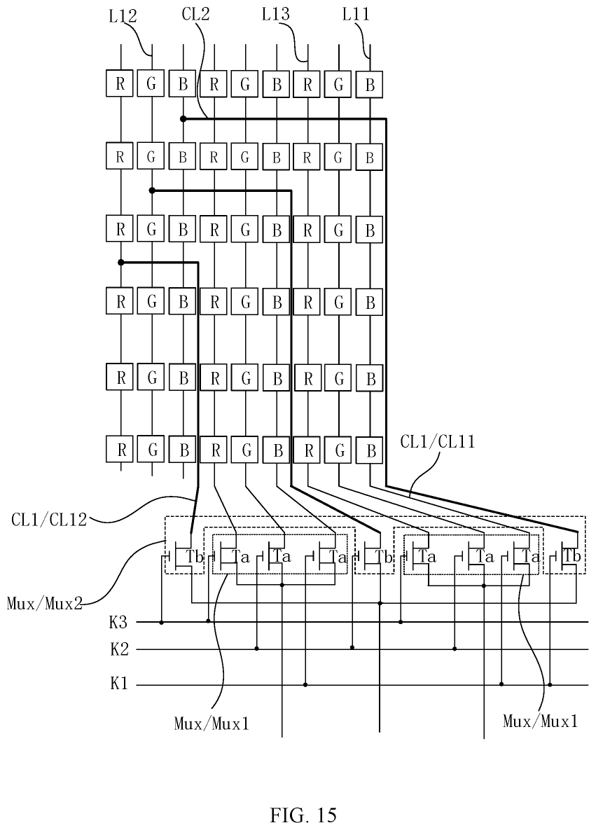

FIG. 15 is a partial schematic diagram of a display panel according to one or more embodiments of the present disclosure.

In some embodiments of the present disclosure, as shown in FIG. 15, along the first direction X, the second switch Tb is located between adjacently arranged first multiplexers MUX1. That is, the second switch Tb is not located between adjacent first switches Ta in the same first multiplexer MUX1. The first switches Ta in the first multiplexer MUX1 are collectively arranged, so the layout difficulty of the third connection line electrically connected to the input terminal of the first multiplexer MUX1 and the control line electrically connected to the control terminal of the first multiplexer MUX1 is reduced.

In some embodiments, as shown in FIG. 14 and FIG. 15, along the first direction X, any two adjacent second switches Tb in multiple second switches Tb in the same second multiplexer MUX2 are spaced apart by the first switch Ta.

In the display region AA, the first signal line L1 and the second connection line CL2 are both arranged between adjacent sub-pixels. Since the gap between adjacent sub-pixels is limited, the first portion CL21 and the first signal line L1 that are arranged adjacently and in parallel can be arranged in the gap between one pair of adjacent sub-pixels, but the quantity of the first portion CL21 is limited. Therefore, in the first display sub-region AA1, two first portions CL21 are generally not arranged compactly. That is, in the gap between adjacent first portions CL21, the first signal line L1 in the first display sub-region AA1 is generally arranged.

In this embodiment, in the gap between two adjacent second switches Tb that are electrically connected to different first portions CL21, the first switch Ta electrically connected to the first signal line L1 in the first display sub-region AA1 is arranged. In this way, it is easy to electrically connect the first switch Ta and the second switch Tb to their neighboring proximity signal line L0.

In some embodiments, as shown in FIG. 15, at least two first multiplexers MUX1 adjacent along the first direction X are spaced apart by one first switch Tb. That is, along the first direction X, at least one first multiplexer MUX1 is arranged between two adjacent second switches Tb. Therefore, the second switches Tb are distributed dispersedly.

Accordingly, the first portions CL21 may be distributed dispersedly in the display region AA, reducing the layout difficulty of the second connection lines CL2 in the display region AA.

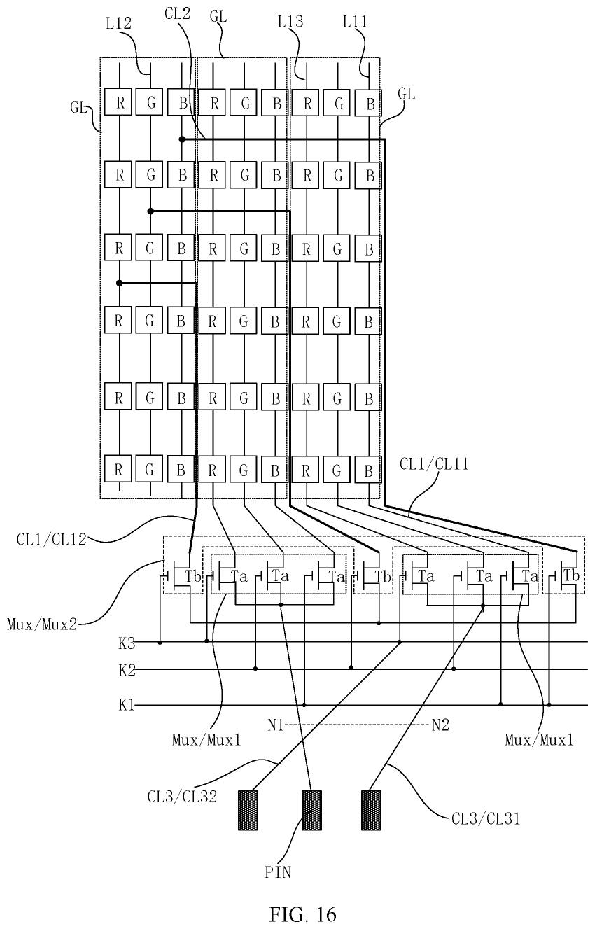

FIG. 16 is a partial schematic diagram of a display panel according to one or more embodiments of the present disclosure.

In some embodiments, as show in FIG. 16, the first signal lines L1 in the first display sub-region AA1 and the first signal lines L1 in the second display sub-region AA2 constitute a 1^{st} first-signal-line group GL to a N^{th} first-signal-line group GL that are arranged along the first direction X. Multiple first signal lines L1 in the display region AA are divided into N first-signal-line groups GL. According to the arrangement sequence along the first direction, the N first-signal-line groups GL are referred to as the 1^{st} first-signal-line group to the N^{th} first-signal-line group respectively.

Any first-signal-line group GL includes at least two first signal lines L1 that are arranged along the first direction and adjacent to one another. The N first-signal-line groups GL are identical in the quantity of first signal lines L1. For example, each first-signal-line group GL includes N first signal lines L1 including the Type-1 signal line L11 to the Type-M signal line.

The first non-display sub-region NA1 further includes the first pin PIN to the N^{th} pin PIN that are arranged along the first direction X. The pins PIN are electrically connected to the input terminals of the multiplexers MUX. For example, the pin PIN may be electrically connected to the input terminal of the corresponding multiplexer MUX through the third connection line, and the pin PIN may be bonded to the drive chip.

Along the first direction X, the selection output terminals of the multiplexer MUX that is electrically connected to the i^{th} pin PIN are electrically connected to the first signal lines L1 in the i^{th} first-signal-line group CL, 1≤i≤N. For example, from left to right, the first pin PIN is electrically connected to the first signal lines L1 in the 1st first-signal-line group through the multiplexer MUX, the second pin PIN is electrically connected to the first signal lines L1 in the 2 nd first-signal-line group through another multiplexer MUX, . . . , and the N^{th} pin PIN is electrically connected to the first signal lines L1 in the N^{th} first-signal-line group through another multiplexer MUX.

In the present embodiment, the arrangement sequence of multiple pins PIN is the same as the arrangement sequence of the first-signal-line groups GL that are electrically connected to the multiplexers MUX electrically connected to multiple pins PIN. Therefore, the drive chip bonded to the pins PIN may be the drive chip in the existing art, reducing the research cost of the drive chip.

In some embodiments of the present disclosure, as shown in FIG. 13, multiple multiplexers MUX further include a third multiplexer MUX3. The third multiplexer MUX3 includes a first switch Ta electrically connected to the first signal line L1 in the first display sub-region AA1 and a second switch Tb electrically connected to the first signal line L1 in the second display sub-region AA2.

The pin PIN electrically connected to the third multiplexer MUX3 is located between the pin PIN electrically connected to the first multiplexer MUX1 and the pin PIN electrically connected to the second multiplexer MUX2. The pin PIN electrically connected to the first multiplexer MUX1 and the pin PIN electrically connected to the second multiplexer MUX2 are arranged along the first direction X and are adjacent.

As shown in FIG. 16, the first non-display sub-region NA further includes third connection lines CL3, and the pins PIN are electrically connected to the input terminals of the multiplexers MUX through the third connection lines CL3. In this regard, the third connection line CL3 is used for connecting the pin PIN to the input terminal of the corresponding multiplexer MUX.

In this embodiment, the second switches Tb in at least one or more second multiplexers MUX2 are dispersed between different pairs of adjacent first switches Ta, so the input terminals of at least one or more second multiplexers MUX2 are located between the input terminals of adjacent first multiplexers MUX1. In order to achieve the configuration that the arrangement sequence of the pins PIN electrically connected to the input terminals of these multiplexers MUX is the same as the arrangement sequence of the first-signal-line groups GL, the third connection lines CL3 electrically connected to the input terminals of at least one or more second multiplexers MUX2 cross the third connection lines CL3 electrically connected to the input terminals of at least one or more first multiplexers MUX1.

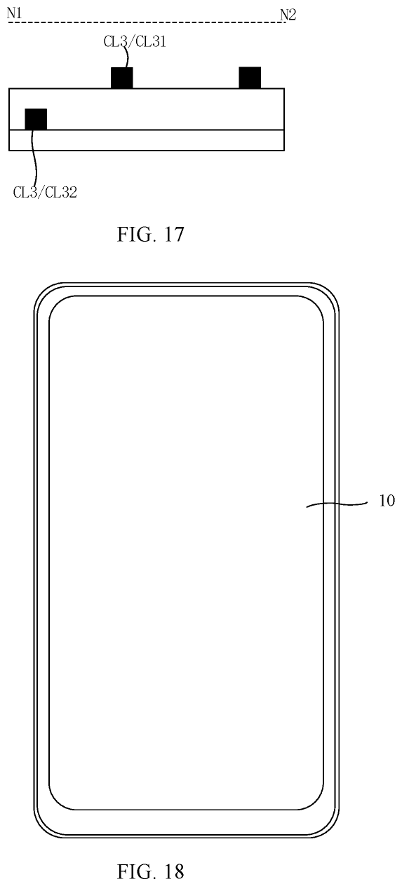

FIG. 17 is a cross-sectional view taken along line N1-N2 in shown FIG. 16.

In some embodiments, as shown in FIG. 17, the third connection line CL31 electrically connected to the input terminal of the first multiplexer MUX1 and the third connection line CL31 electrically connected to the input terminal of the second multiplexer MUX2 are located in different conductive layers.

FIG. 18 is a schematic diagram of a display apparatus according to one or more embodiments of the present disclosure.

Embodiments of the present disclosure further provide a display apparatus. As shown in FIG. 18, the display apparatus includes the display panel 10 provided in any of the above embodiments. For example, the display apparatus may be an electronic apparatus such as a mobile phone, a computer, a smart wearable apparatus (such as a smart watch), a vehicle-mounted display apparatus, and the like. The display apparatus is not limited to these electronic apparatuses.

On the one hand, the multiplexers MUX are located between the pins and the first connection lines. Therefore, the first connection lines have a short length, and the width along the first direction occupied by multiple multiplexers MUX is greater than the width along the first direction occupied by multiple pin regions that are electrically connected to multiple multiplexers MUX respectively. In this way, the short-circuiting risk between adjacent first connection lines is reduced, and the layout difficulty is reduced. On the other hand, the quantity of the connection lines between the multiplexers MUX and the pins electrically connected to the multiplexers MUX is significantly reduced, and the short-circuiting risk and the layout difficulty of these connection lines are significantly reduced.

The above are merely some embodiments of the present disclosure, which, as mentioned above, are not intended to limit the present disclosure. Within the principles of the present disclosure, any modification, equivalent substitution, improvement shall fall into the protection scope of the present disclosure.

What is claimed is:

1. A display panel, comprising:
a non-display region comprising a first non-display sub-region comprising multiplexers and first connection lines, wherein one of the multiplexers comprises at least two selection output terminals electrically connected to first ends of the first connection lines; and
a display region comprising a first display sub-region and a second display sub-region located on at least one side of the first display sub-region along a first direction, wherein the first display sub-region and the first non-display sub-region are arranged along a second direction that crosses the first direction, each of the first display sub-region and the second display sub-region comprises first signal lines arranged along the first direction, and the display region further comprises second connection lines,
wherein the first connection lines comprise a first connection sub-line and a second connection sub-line, at least one of the first signal lines in the first display sub-region is electrically connected to a second end of the first connection sub-line, and at least one of the first signal lines in the second display sub-region is electrically connected to a second end of the second connection sub-line through the second connection line.

2. The display panel according to claim 1, wherein the first signal lines comprise Type-1 signal lines to Type-M signal lines, where M is a positive integer greater than 2,
wherein among the Type-1 signal lines to the Type-M signal lines, sub-pixels that are electrically connected to the first signal lines of a same type have a same color, and at least two of sub-pixels electrically connected to the first signal lines of different types have different colors, and
wherein each of the multiplexers is electrically connected to the Type-1 signal line to the Type-M signal line.

3. The display panel according to claim 2, wherein the Type-1 signal line to the Type-M signal line electrically connected to each of the multiplexers are sequentially arranged adjacent to one another along the first direction, and
wherein, for the Type-1 signal line to the Type-M signal line that are electrically connected to a same one of the multiplexers, no other first signal line is arranged between any two first signal lines that are arranged adjacent along the first direction.

4. The display panel according to claim 1, wherein the multiplexers comprise first multiplexers and second multiplexers,
wherein the at least two selection output terminals of one of the first multiplexers are electrically connected to first signal lines in the first display sub-region through the first connection sub-lines, and the at least two selection output terminals of the second multiplexer are electrically connected to the first signal lines in the second display sub-region through the second connection sub-lines and the second connection lines.

5. The display panel according to claim 4, wherein the multiplexers further comprise a third multiplexer, at least one of the at least two selection output terminals of the third multiplexer is electrically connected to the first signal line in the second display sub-region through the first connection sub-line, and another at least one of the at least two selection output terminals of the third multiplexer is electrically connected to the first signal line in the first display sub-region through the second connection sub-line and the second connection line.

6. The display panel according to claim 3, wherein the at least two selection output terminals comprise Type-1 selection output terminal to Type-M selection output terminal, and the Type-1 signal line to the Type-M signal line are electrically connected to the Type-1 selection output terminal to the Type-M selection output terminal in a one-to-one correspondence manner,
wherein, for the Type-1 signal line to the Type-M signal line and the Type-1 selection output terminal to the Type-M selection output terminal corresponding to a same one of the multiplexers, an arrangement sequence of the Type-1 signal line to the Type-M signal line along the first direction is the same as an arrangement sequence of the Type-1 selection output terminal to the Type-M selection output terminal along the first direction.

7. The display panel according to claim 3, wherein an arrangement sequence of the multiplexers along the first direction is the same as an arrangement sequence of Type-k signal lines along the first direction that are electrically connected to the multiplexers respectively, where 1≤k≤M.

8. The display panel according to claim 7, wherein a layer where the first connection sub-line is arranged is different from a layer where the second connection sub-line is arranged.

9. The display panel according to claim 1, wherein one of the second connection lines comprises a first portion and a second portion, the second portion is connected between the first portion and one of the first signal lines in the second display sub-region, and the first portions of the second connection lines are arranged along the first direction,
wherein one of the multiplexers comprises selection output terminals, the first portion and the first signal line located in the first display sub-region are proximity signal lines, and an arrangement sequence of the selection output terminals along the first direction is the same as an arrangement sequence of the proximity signal lines electrically connected to the selection output terminals along the first direction.

10. The display panel according to claim 9, wherein the first non-display sub-region is further provided with pins arranged along the first direction and electrically connected to input terminals of the multiplexers, and
wherein an arrangement sequence of the pins along the first direction is the same as the arrangement sequence of the multiplexers electrically connected to the pins along the first direction.

11. The display panel according to claim 9, wherein one of the multiplexers is electrically connected to at least three first signal lines, and at least one of the at least three first signal lines electrically connected to the multiplexer is located in the first display sub-region.

12. The display panel according to claim 9, wherein one of the multiplexers is electrically connected to at least three first signal lines, and at least one of the at least three first signal lines electrically connected to the multiplexer is located in the second display sub-region.

13. The display panel according to claim 1, wherein the multiplexers comprise first multiplexers and second multiplexers,
wherein one of the first multiplexers comprises first switches, and an output terminal of one of the first switches is electrically connected to one of the first signal lines in the first display sub-region through the first connection sub-line,
wherein one of the second multiplexers comprises second switches, an output terminal of one of the second switches is electrically connected to one of the first signal lines in the second display sub-region through the second connection sub-line and the second connection line, and
wherein in at least one of the second multiplexers, along the first direction, the first switch is arranged between at least two adjacent second switches of a same second multiplexer.

14. The display panel according to claim 13, wherein, along the first direction, the second switches are located between the first multiplexers that are adjacently arranged.

15. The display panel according to claim 14, wherein, along the first direction, one second switch is arranged between at least two first multiplexers that are adjacently arranged.

16. The display panel according to claim 13, wherein the first signal lines in the first display sub-region and the first signal lines in the second display sub-region constitute a 1^{st} first-signal-line group to an N^{th} first-signal-line group that are arranged along the first direction, and each first-signal-line group comprises at least two first signal lines that are adjacently arranged along the first direction,
wherein the first non-display sub-region is further provided with a Pt pin to an N^{th} pin that are arranged along the first direction, and the Pt pin to the N^{th} pin are electrically connected to input terminals of the multiplexers, and
wherein, along the first direction, the selection output terminals of the multiplexer electrically connected to an i^{th} pin are electrically connected to the first signal lines in the i^{th} first-signal-line group, where 1≤i≤N.

17. The display panel according to claim 16, wherein the first non-display sub-region is further provided with third connection lines, and the pins are electrically connected to the input terminals of the multiplexers through the third connection lines, and
wherein a layer where the third connection line electrically connected to the input terminal of the first multiplexer is located is different from a layer where the third connection line electrically connected to the input terminal of the second multiplexer is located.

18. The display panel according to claim 16, wherein the multiplexers further comprise a third multiplexer comprising the first switch and the second switch, and
wherein the pin electrically connected to the third multiplexer is located between the pin connected to the first multiplexer and the pin electrically connected to the second multiplexer, the pin connected to the first multiplexer and the pin electrically connected to the second multiplexer being adjacent to one another along the first direction.

19. A display apparatus, comprising a display panel comprising:
a non-display region comprising a first non-display sub-region, wherein the first non-display sub-region is provided with multiplexers and first connection lines, one of the multiplexers comprises at least two selection output terminals electrically connected to first ends of the first connection lines; and
a display region comprising a first display sub-region and a second display sub-region located on at least one side of the first display sub-region along a first direction, wherein the first display sub-region and the first non-display sub-region are arranged along a second direction that crosses the first direction, each of the first display sub-region and the second display sub-region is provided with first signal lines arranged along the first direction, and the display region further comprises second connection lines,
wherein the first connection lines comprise a first connection sub-line and a second connection sub-line, at least one of the first signal lines in the first display sub-region is electrically connected to a second end of the first connection sub-line, and at least one of the first signal lines in the second display sub-region is electrically connected to a second end of the second connection sub-line through the second connection line.
